(19) United States
(12) Patent Application Publication
(10) Pub. No.: US 2019/0185990 A1
(43) Pub. Date: Jun. 20, 2019

(54) EVAPORATOR, EVAPORATION COATING APPARATUS AND EVAPORATION COATING METHOD

(71) Applicant: BOE TECHNOLOGY GROUP CO., LTD., Beijing (CN)

(72) Inventor: Dejiang ZHAO, Beijing (CN)

(73) Assignee: BOE TECHNOLOGY GROUP CO., LTD., Beijing (CN)

(21) Appl. No.: 15/563,543

(22) PCT Filed: Apr. 1, 2017
(86) PCT No.: PCT/CN2017/079293

§ 371 Date: Sep. 29, 2017

(30) Foreign Application Priority Data
Jul. 27, 2016 (CN) 201610605160.8

(51) Int. Cl. C23C 14/54; C23C 14/26

(52) U.S. Cl. CPC C23C 14/543; C23C 14/541; C23C 14/26

(57) ABSTRACT

An evaporator includes at least one feeding member and a heating member. Each feeding member is configured to transfer a source material in a transfer speed that is adjustable, and the heating member is configured to heat the source material transferred by the feeding member for evaporation to thereby generate a source material vapor. An evaporation coating apparatus further includes a coating chamber, an object holder, and a controller configured to control the transfer speed, wherein the evaporator and the object holder are both disposed inside the coating chamber, the object holder is configured to provide a platform for placing an object to be coated thereon, and the coating chamber is configured to provide an environment for the source material vapor vented out from the evaporator to attach to the object to thereby form a film of the source material onto the object.

### CROSS-REFERENCE TO RELATED APPLICATION

The present application claims priority to Chinese Patent Application No. 201610605160.8 filed on Jul. 27, 2016, the disclosure of which is hereby incorporated by reference in its entirety.

### TECHNICAL FIELD

The present disclosure is related generally to the field of coating technologies, and more specifically to an evaporator, an evaporation coating apparatus, and a method of evaporation coating.

### BACKGROUND

An evaporation coating equipment, or an evaporation deposition equipment, is a device that is frequently used to coat an object. The object to be coated can be an electronic component, such a substrate of an electronic apparatus. The object can be coated with the a source material to form a coating layer, a film, or a membrane of specified composition and thickness. The evaporation coating equipment is frequently employed during fabrication of some electronic devices, such as an organic light-emitting diode (OLED) display panel.

A typical evaporation coating apparatus usually includes a coating chamber, and an evaporator disposed in the coating chamber. The coating chamber is configured to provide an environment (such as a vacuum) for coating, and the evaporator is configured to evaporate a source material (i.e., a coating material) such that the source material vapor can attach to, or deposit onto, the substrate, thereby forming a layer or a film of the source material on the substrate.

In a conventional evaporation coating technology, the evaporator typically includes a furnace and a heating wire. The furnace is usually configured to provide a space for holding a source material, i.e., the source material is typically placed in the furnace. The heating wire is usually arranged to surround the furnace and is configured to heat the furnace.

During the process of evaporation coating, after the coating chamber is opened, the source material is disposed in the furnace, and the substrate is disposed over the furnace. After the coating chamber is closed, the furnace is heated by means of the heating wire. Upon heating, the source material is evaporated and the source material vapor becomes attached onto (or deposits) the substrate to thereby obtain a coated substrate having a layer of the source material coated thereon. Finally, the coated substrate is taken out of the coating chamber.

### SUMMARY

The inventors of the present disclosure have recognized the following issues with respect to conventional evaporation coating technologies such as the one as described above. If there is a relatively large amount of source material, the source material tends to be piled together, and if there is further an uneven heating, some of the source material can become carbonized. These effects can severely influence the normal evaporation coating process, and can also result in a waste of source materials.

More specifically, the evaporator is typically disposed inside a coating chamber, and in order to prevent the air in the environment from contaminating the coating chamber, the coating chamber is not opened once the evaporation coating process starts. As such, all of the source material needs to be placed in the furnace, but this can lead to a relatively large amount of the source material being piled up in the furnace. As such, it can easily result in the carbonization of some of the source material. This is further compounded by the uneven temperature.

In order to address the issues associated with current evaporation coating technologies, the present disclosure provides an evaporator, an evaporation coating apparatus, and a method of evaporation coating.

In a first aspect, an evaporator is disclosed.

The evaporator comprises at least one feeding member and a heating member. Each feeding member is configured to transfer a source material in a transfer speed that is adjustable. The heating member is configured to heat the source material transferred by the feeding member for evaporation to thereby generate a source material vapor.

In some embodiments of the evaporator, each feeding member is configured to transfer the source material to the heating member in portions, wherein each portion of the source material is transferred to the heating member in a time period, and the time period for each portion is adjustable to thereby realize that the transfer speed is adjustable.

As such, in the evaporator, the source material can be in a form of grains, and each feeding member can comprise a dispenser, which is configured to adjustably dispense the grains of the source material to allow the source material to be transferred to the heating member.

In order to adjustably dispense the grains of the source material as described above, the dispenser can comprise a vane wheel, and the vane wheel is configured to rotate to thereby dispense the grains of the source material for transferring to the heating member. As such, the vane wheel can be coupled with a controller, which is configured to adjust a rotation speed of the vane wheel to thereby realize that the transfer speed of the source material is adjustable.

In some embodiments of the evaporator, each feeding member comprises a storage portion and a transfer portion. The storage portion is configured to store the source material before transferring to the transfer portion; and the transfer portion is configured to transfer the source material from the storage portion to the heating member.

The storage portion can comprise a preheating subportion, which is configured to preheat the source material in the storage portion.

In the above mentioned embodiments, the evaporator can further include an evaporation chamber. As such, the heating member can be disposed inside the evaporation chamber. The storage portion of each feeding member can be disposed outside the evaporation chamber. The evaporation chamber can be provided with a vapor outlet, which is configured to vent the source material vapor out of the evaporation chamber for subsequent coating onto a substrate.

The evaporation chamber can be provided with a temperature controlling portion, configured to maintain a temperature of the evaporation chamber to thereby prevent the source material vapor from solidifying on an inner side of the evaporation chamber. The temperature controlling portion as described above can comprise a heating wire surrounding the evaporation chamber.

In some embodiments of the evaporator, the evaporation chamber comprises a vapor flow stabilizing plate. The vapor flow stabilizing plate is disposed inside the evaporation chamber to separate the heating member and the vapor outlet, and provided with a plurality of openings, which are configured to allow the source material vapor generated from the heating member to move therethrough to subsequently vent out of the evaporation chamber through the vapor outlet.

In some embodiments of the evaporator as mentioned above, each opening of the vapor flow stabilizing plate has a substantially same size and shape, and a region closer to a center of the vapor flow stabilizing plate is configured to have a higher distribution density of openings.

In some embodiments of the evaporator, each feeding member can be configured to transfer a source material of a parameter, wherein the parameter comprises at least one of a composition, a shape, or a size. As such, each feeding member can be configured to transfer one different type of source material (i.e. having different compositions), or can be configured to transfer a same type source material, but with different shapes or sizes.

In some embodiments of the evaporator, the heating member comprises a heating groove. As such, the source material from the at least one feeding member can be transferred into the heating groove, and the heating groove can comprise a bottom wall, and a side wall surrounding an edge of the bottom wall, wherein the bottom wall and the side wall are configured to be both able to heat.

In a second aspect, the present disclosure further provides an evaporation coating apparatus.

The evaporation coating apparatus comprises an evaporator according to any one of the embodiments as described above.

According to some embodiments of the present disclosure, the evaporation coating apparatus further comprises a coating chamber, an object holder, and a controller configured to control the transfer speed.

The evaporator and the object holder are both disposed inside the coating chamber. The object holder is configured to provide a platform for placing an object to be coated thereon. The coating chamber is configured to provide an environment for the source material vapor vented out from the evaporator to attach to the object to thereby form a film of the source material onto the object.

According to some embodiments of the present disclosure, the evaporation coating apparatus further comprises a film thickness detector, which is configured to detect a rate of thickness change for the film of the source material coated onto the substrate. As such, the film thickness detector as described above can comprise a crystal oscillator.

In a third aspect, the present disclosure further provides a method for evaporation coating of a source material on an object utilizing an evaporation coating apparatus.

The evaporation coating apparatus as utilized in the above mentioned method comprises an evaporator, a coating chamber, and an object holder, wherein the evaporator comprising at least one feeding member and a heating member.

The method comprising the following steps:

placing the source material in the at least one feeding member and closing off the coating chamber;

starting the heating member until a temperature of the heating member is higher than a gasification temperature of the source material; and

the at least one feeding member transferring the source material to the heating member in a transfer speed that is adjustable to thereby obtain a source material vapor before the source material vapor attaches to the object to thereby form a film of the source material thereon.

Between the starting the heating member until a temperature of the heating member is higher than a gasification temperature of the source material and the at least one feeding member transferring the source material to the heating member in a transfer speed that is adjustable, the method can further comprise the following step:

adjusting a power of the heating member such that the temperature of the heating member is maintained at a level higher than the gasification temperature of the source material.

Prior to the at least one feeding member transferring the source material to the heating member in a transfer speed that is adjustable, the method can further comprise the following step:

preheating the source material.

In some embodiments of the method, the evaporation coating apparatus further comprises a film thickness detector configured to detect a rate of thickness change for the film of the source material coated onto the object. As such, in the method, the at least one feeding member transferring the source material to the heating member in a transfer speed that is adjustable can comprise the following sub-steps:

the at least one feeding member transferring the source material to the heating member;

periodically detecting a rate of thickness change for the film of the source material coated onto the object; and

adjusting a transfer speed of the source material based on the rate of thickness change for the film of the source material, such that a difference between the rate of thickness change and a preset rate of thickness change is smaller than a preset value.

In the method, the adjusting a transfer speed of the source material based on the rate of thickness change for the film of the source material can comprise the following sub-steps:

comparing the rate of thickness change for the film of the source material with a preset rate of thickness change; and

reducing the transfer speed of the source material if the rate of thickness change for the film of the source material is larger than the preset rate of thickness change; or

increasing the transfer speed of the source material if the rate of thickness change for the film of the source material is smaller than the preset rate of thickness change.

Other embodiments may become apparent in view of the following descriptions and the attached drawings.

### BRIEF DESCRIPTION OF THE DRAWINGS

To more clearly illustrate some of the embodiments provided in the present disclosure, the following is a brief description of the drawings. The drawings, as well as the descriptions thereof that follow, are only illustrative of some embodiments, and may not cover other embodiments. For those of ordinary skill in the art, drawings of other embodiments can become apparent based on these drawings.

FIG. 1 is a schematic diagram of an evaporator according to some embodiments of the present disclosure;

FIG. 2A is a schematic diagram of an evaporator according to some implementations of the present disclosure;

FIG. 2B illustrates a top plan view of the vapor flow stabilizing plate as shown in

FIG. 2A;

FIG. 2C is a schematic diagram of an evaporator according to some other embodiments of the present disclosure;

FIG. 2D is a schematic diagram of a feeding member of the evaporator according to some embodiments of the present disclosure;

FIG. 3 is a flow chart of an evaporation coating method according to some embodiments of the present disclosure;

FIG. 4A is a flow chart of an evaporation coating method according to some other embodiments of the present disclosure;

FIG. 4B is a schematic diagram of an evaporation coating apparatus utilized in the evaporation coating method as shown in FIG. 4A;

FIG. 4C is a flow chart of adjusting a transfer speed of the source material according to some embodiments of the present disclosure.

The drawings as briefly described above provide an illustration of some of the embodiments provided in the present disclosure, and a detailed description of the drawings can be found in the following. It is noted that the drawings and the description thereof are for the purpose of illustration only, and do not impose limitations on the scope of the present disclosure.

### DETAILED DESCRIPTION

In the following, with reference to the drawings of various embodiments as disclosed herein, the technical solutions of the embodiments of the disclosure will be described in a clear and fully understandable way.

In order to address the issues associated with current evaporation coating technologies, such as the aforementioned issue of carbonization of the source material due to piling up of the source material and uneven heating, the present disclosure provides an evaporator, an evaporation coating apparatus, and a method of evaporation coating.

In a first aspect, an evaporator is disclosed. The evaporator comprises at least one feeding member and a heating member. Each feeding member is configured to transfer a source material to the heating member, wherein a transfer speed of the source material is adjustable. The heating member is configured to heat the source material transferred by the feeding member for evaporation to thereby generate a source material vapor.

According to some embodiments of the evaporator, each feeding member is configured to transfer the source material to the heating member in portions. For example, each portion is transferred in one time period, wherein the one time period for each portion is adjustable.

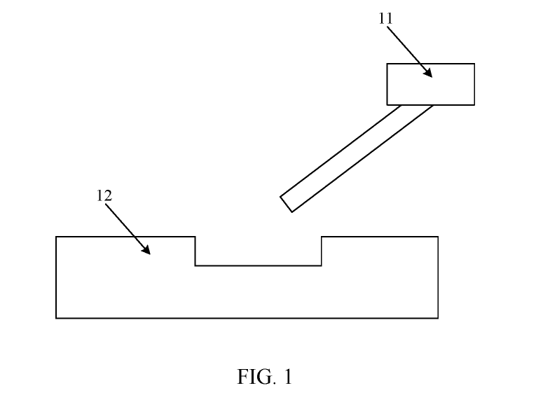

FIG. 1 illustrates an evaporator according to some embodiments of the present disclosure. As shown in FIG. 1, the evaporator comprises a feeding member 11 and a heating member 12.

The feeding member 11 is configured to store a source material and to feed, or transfer, the source material to the heating member 12 for n time periods, where n is an integer ≥2. In some embodiments, the n time periods are sequential and continuous time periods. In some other embodiments, the n time periods are not continuous, and can have time gaps in between. According to some embodiments, the n time periods each can have a same time span. According to some other embodiments, the n time periods can have different time spans. Similarly, the gaps between two consecutive time periods can have the same, or different, length. The sequence of the n time periods can be controlled, for example, digitally using a processor.

Correspondingly, the source material can be divided into a total of n portions, and the feeding member 11 can transfer one portion of the source material to the heating member for evaporation each time. The heating member 12 is configured to heat the source material transferred by the feeding member such that the source material is evaporated and becomes a source material vapor.

In the evaporator as described above, the feeding member is configured to transfer the source material to the heating member in portions, one time period for each portion. For example, the feeding member is configured to divide the source material stored therein into a plurality of portions for feeding to the heating member such that one portion of the source material is transferred to the heating member for evaporation to thereby turn into the source material vapor for each of the n time periods.

In some embodiments, each portion of the source material can have a substantially equal mass. According to some other embodiments, different portions can have different masses. The portion sizes can be controlled or programmed, for example, using a processor based on the specific needs.

In the embodiments of the evaporator as described above, through the feeding member 11, the source material can be divided into multiple portions. One portion of the source material can be fed to the heating member 12 each time period. As such, source material carbonization can be reduced. The consequent detrimental effects on the evaporation coating process resulting from the piling up of a relatively large amount of source material in the heating member, and to an uneven heating by the heating member as well, can also be effectively solved.

According to some embodiments as described above, because there is a relatively small amount of source material for evaporation during each time period in the heating member, a relatively even heating can be realized. Carbonization is of the source material in the heating member is therefore reduced or inhibited.

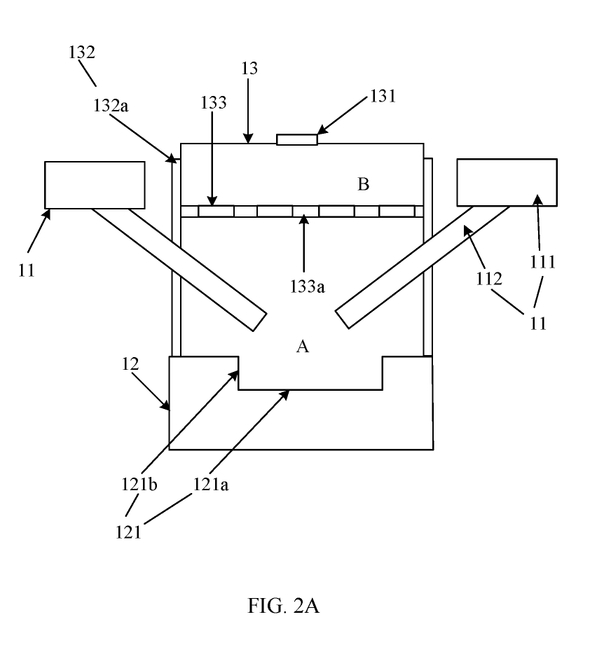

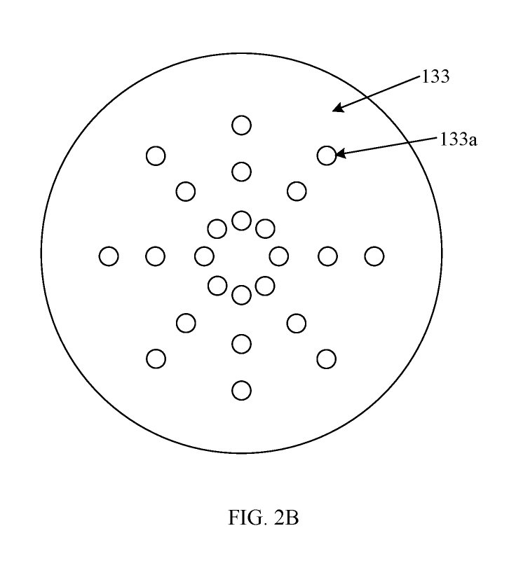

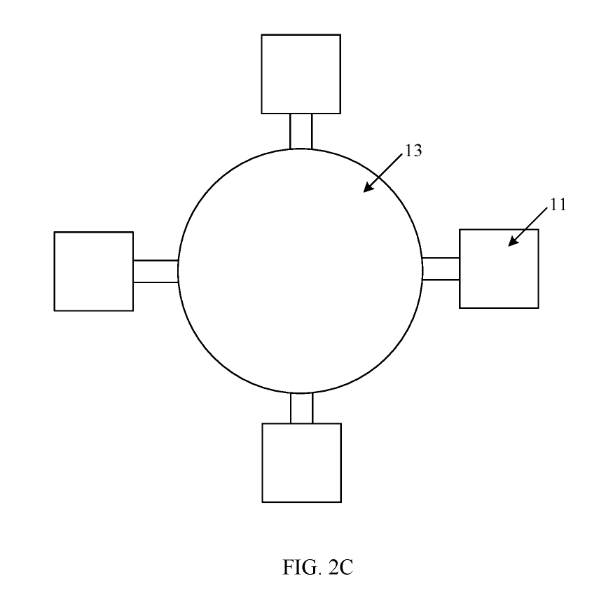

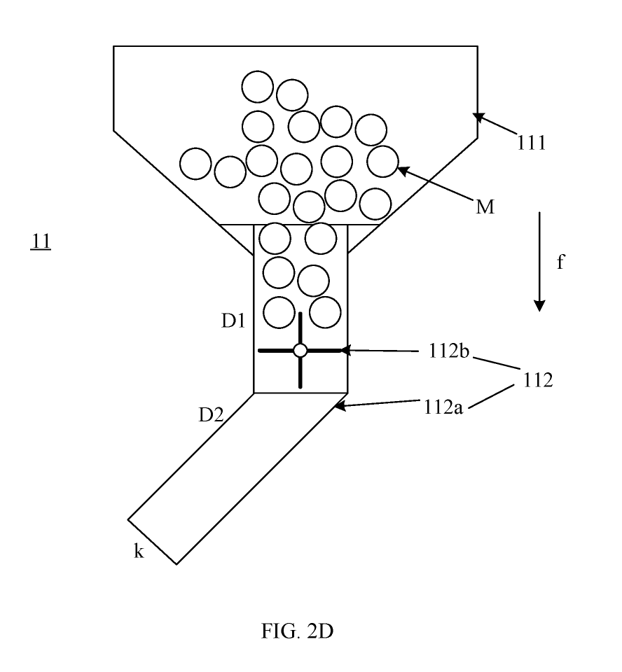

FIG. 2A illustrates an evaporator according to some implementations. As shown, the feeding member 11 can comprise a storage portion 111 and a transferring portion 112. The storage portion 111 is configured to store the source material, and the transferring portion 112 is configured to feed or transfer the source material to the heating member 12 for the n time periods.

In some embodiments, the source material can be an organic electro-luminescence (OEL) material. For example, the evaporator according to the aforementioned embodiments can be applied to form an organic layer of organic light-emitting diodes (OLEDs) on the to-be-coated object, such as a substrate. The substrate coated with the OLED material can be an important component of, for example, an OLED display.

According to some embodiments, the evaporator 10 can further comprise an evaporation chamber 13, wherein the heating member 12 is disposed inside the evaporation chamber 13. The evaporation chamber 13 is provided with a vapor outlet 131, which is configured to vent the source material vapor out of the evaporation chamber 13.

The substrate or object to be coated can be disposed directly over the vapor outlet 131. In an example, the feeding member 11 can feed the source material to the heating member 12 within a series of 5-10 time periods, to thereby realize a stable flow of the source material vapor.

Additionally, because the evaporator as described above can evaporate one portion of the source material each time, the efficiency of evaporation coating can be improved.

The storage portion 111 is arranged outside the evaporation chamber 13, so as to reducing heating of the storage portion 111 by the evaporation chamber, thereby avoiding detrimental effects on the source material from a higher temperature inside the storage portion 111.

According to some embodiments of the evaporator, the storage portion 111 can be provided with a preheating subportion 111a, which is configured to preheat the source material in the storage portion 111. The process of preheating can avoid a sharp increase of the temperature of the source material after the source material enters the heating member 12, which can damage the source material. The preheating temperature can be around 80° C. or around 50° C., and can be configured based on practical needs. The preheating subportion 111a can comprise a first heating wire surrounding the storage portion 111.

According to some embodiments of the evaporator, the evaporation chamber 13 can be provided with a temperature controlling portion 132, which is configured to control a temperature in the evaporation chamber 13. The temperature controlling portion 132 can comprise a second heating wire 132a, which is disposed to surround the evaporation chamber 13.

The second heating wire 132a is configured to maintain a relatively high temperature inside the evaporation chamber 13, to thereby prevent the source material vapor from solidifying while moving upward, and to prevent the source material vapor from solidifying and depositing onto an inner wall of the evaporation chamber 13 after the source material vapor contacts an inner wall of the evaporation chamber 13, which can result in a waste of the source material.

In some embodiments, the temperature controlling portion 132 can comprise other sub-portions, such as an electromagnetic heater or an infrared heater. There are no limitations herein.

According to some embodiments of the evaporator, the evaporation chamber 13 can be provided with a vapor flow stabilizing plate 133, which is disposed inside the evaporation chamber 13. The vapor flow stabilizing plate 133 is provided with a plurality of openings 133a. The evaporation chamber 13 can be partitioned into two cavities by the vapor flow stabilizing plate 133, wherein the heating member 12 is disposed in one of the two cavities (e.g., cavity A), and the vapor outlet 131 is connected to another one of the two cavities (e.g., cavity B). The plurality of openings 133a are configured to provide a passageway for the source material vapor generated by the heating member 12 in cabinet A to cabinet B.

FIG. 2B illustrates a top view of the vapor flow stabilizing plate 133 shown in FIG. 2A according to some embodiments of the present disclosure. The plurality of openings 133a on the vapor flow stabilizing plate 133 are illustrated in FIG. 2B, wherein each of the openings 133a has a substantially same size and shape, and the closer the openings are to a center of the vapor flow stabilizing plate 133, the more openings 133a are arranged. That is, in the embodiment shown, the openings closer to the center of the vapor flow stabilizing plate 133 are arranged to have a higher distribution density.

Such a distribution of the plurality of openings 133a can be configured to allow the source material vapor to scatter to thereby prevent the source material vapor from gathering to negatively influence the coating effect. Therefore, the vapor flow stabilizing plate 133 effectively redistributes the source material vapor as desired.

It is noted that the sizes, shapes, and distribution of the openings 133a as described above and illustrated in FIG. 2B represent only some embodiments of the present disclosure. Other embodiments can have openings configured to be of different sizes, shapes, or distribution, and can be configured to scatter the source material vapor in a different distribution as desired.

As shown in FIG. 2A, the heating member 12 includes a heating groove 121, which comprises a bottom wall 121a and a side wall 121b that surrounds an edge of the bottom wall 121a. As such, the feeding member 11 can be configured to transfer the source material into the heating groove 121 of the heating member 12 within the n time periods.

The bottom wall 121a and the side wall 121b of the heating groove 121 can be configured to both heat the source material disposed therein, resulting in an improved heating effect to thereby elevating the evaporation speed. The heating groove 121 can heat via a manner of resistance wire heating (e.g., a third heating wire), or a manner of induction heating. In some embodiments, the heating member 12 can comprise components other than those as described above for heating. For example, the heating member 12 can include an electron-beam heater. There are no limitations on the manner and structure of heating by the heating groove 121.

According to some embodiments of the present disclosure, the evaporator 10 can include at least two feeding members 11, and each feeding member 11 is configured to store the source material and to transfer the source material to the heating member 12 for n time periods.

FIG. 2A illustrates an embodiment of the evaporator comprising two feeding members 11. In some embodiments, there can be more than two feeding members 11. For example, four, five, or more feeding members 11 can be included in the evaporator 10.

In the embodiment of the evaporator as shown in FIG. 2C, the evaporator comprises four feeding members 11, which are distributed evenly on a surrounding of the evaporation chamber 13. The number of feeding members in the evaporator is dependent on practical needs, and there are no limitations herein. The distribution of the feeding members 11 can also be uneven according to some embodiments.

In some embodiments of the evaporator, the source material stored in, and transferred by, the at least two feeding members 11 can be in a form of grains. The sizes and shapes of the grains can be configured based on practical needs.

In some embodiments, the source material can be in other forms so long as the source material can be divided into portions for discrete feeding to the heating member of the evaporator

The source material may also need pre-treatment, if taking a shape different from its original shape. For example, if an OLED material is used as the source material, because it can be originally in a form of powder, it may need to be pre-treated to take the form of grains.

The at least two feeding members 11 of the evaporator can be configured to store and transfer the source material of a different parameter. Herein, the parameter can include at least one of a composition, or a grain size, of the source material.

If the source material in each of the at least two feeding members 11 has a same composition but has a different grain size, each feeding member 11 can be controlled to feed the source material stored therein (i.e., the source material corresponding to the each feeding member 11) to the heating member 12, such that the amount of the source material transferred to the heating member 12 corresponding to each feeding member 11 can be accurately controlled to thereby allow the evaporation speed of the source material to be adjusted.

If the source material in each of the at least two feeding members 11 has a different composition, the evaporator can be configured to feed a first source material of a first composition for evaporation coating onto a first substrate, and then to feed a second source material of a second composition for evaporation coating onto a second substrate, and so on. Therefore, after evaporation coating of the first substrate with the first source material of the first composition, there is no need to replenish the source material, and the second substrate can be placed for direct evaporation coating with the second substrate of the second composition, and so on.

If the source material in each of the at least two feeding members 11 has a substantially same parameter, the evaporator having the at least two feeding members 11 as disclosed herein can thus store more of the source material than an evaporator according to a current technology.

FIG. 2D illustrates a feeding member 11 according to some embodiments of the present disclosure. The feeding member 11 as shown in FIG. 2D can be employed in the evaporator 10 as shown in FIG. 2A or FIG. 2C.

As shown in FIG. 2D, the source material in the feeding member 11 is in a form of grains. The transfer speed of the source material can be adjusted, for example, by controlling a number of grains in each time period. In some other embodiments, each portion corresponds to one grain, and the transfer speed can be controlled by adjusting the time sequence of n time periods, such as the duration of each time period, the length of the gap between two consecutive time periods, etc.

In some embodiments, the feeding member 11 comprises a storage portion 111 and a transferring portion 112. The transferring portion 112 includes a feeding channel 112a and a vane wheel 112b.

The vane wheel 112b is disposed inside the feeding channel 112a and separates the feeding channel 112a into a first segment D1 and a second segment D2. The first segment D1 of the feeding channel 112a is connected to the storage portion 111 and is occupied or filled with the source material M. An opening k of the second segment D2 of the feeding channel 112a which is farther away from the vane wheel 112b is arranged over the heating member 12 (not shown in FIG. 2D).

The vane wheel 112b is configured to rotate in a controllable manner to thereby allow a preset number of grains of the source material (for example, one grain of the source material) to pass from the first segment D1 to the second segment D1, and further from the second segment D2 to the heating member 12.

It is noted that FIG. 2D illustrates only one embodiment of the vane wheel 112b. The vane wheel 112b can have other structures or shapes, and there are no limitations herein. It is further noted that besides the vane wheel 112b, a component having a function of dispenser that can dispense the source material in a controllable manner, can also be employed. There are no limitations herein.

According to some embodiments of the present disclosure, the storage portion 111 can have a shape of a funnel, such that one smaller opening of the storage portion 111 is connected to the first segment D1 of the feeding channel 112a. The storage portion 111 is further configured such that a direction of the source material exiting the storage portion (i.e., an exit direction of the source material) f is parallel to a gravitational direction. As such, the source material can spontaneously enter the transferring portion 112 from the storage portion 111 under the gravitational forces.

When the vane wheel 112b is rotating in the transferring portion 112, the source material can be transferred from the first segment D1 to the second segment D2 in the feeding channel 112a, and further from the second segment D2 to the heating member 12. The vane wheel 112b can be driven by a motor, and a rotating speed of the vane wheel 112b can be controlled by manipulating the motor to thereby control the feeding speed of the source material to the heating member 12.

It is noted that the configuration of the feeding member is not limited to that illustrated in FIG. 2D. In some other embodiments, the feeding member can take other configurations to realize a controllable dispensing of the source material from the storage portion 111 through the transferring portion 112 to the heating member 12.

For example, a dispenser other than a vane wheel 112b as shown in FIG. 2D can be employed. If a vane wheel 112b is employed, it can be disposed in a position other than in a middle of the feeding channel 112a of the transferring portion 112 as shown in FIG. 2D (for example, the end corresponding to the opening K, or the end corresponding to another opening of the feeding channel 112a that is connected to the storage portion 111). There are no limitations herein.

In the evaporator as described above, by means of the feeding member which can feed the source material to the heating member 12 for the n time periods, the issue of source material carbonization and the consequent negative effects on the evaporation coating process that is due to the piling up of a relatively large amount of source material in the heating member, and to an uneven heating by the heating member as well, can be effectively solved.

By means of the evaporator as mentioned above, because there is a relatively small amount of source material for evaporation in the heating member, a relatively even heating can be realized, the source material is thus not subject to carbonization, ensuring that the evaporation coating process can normally proceed.

In a second aspect, the present disclosure further provides an evaporation coating apparatus. The evaporation coating apparatus can include an evaporator according to the various embodiments as illustrated in FIG. 1, FIG. 2A, or FIG. 2C.

The evaporation coating apparatus further includes a coating chamber, and an object holder. The evaporator is disposed inside the coating chamber. The object holder is disposed inside the coating chamber and is configured to provide a platform for placing an object to be coated (such as a substrate) thereon.

In a third aspect, the present disclosure provides an evaporation coating method, which can utilize the evaporation coating apparatus as described above.

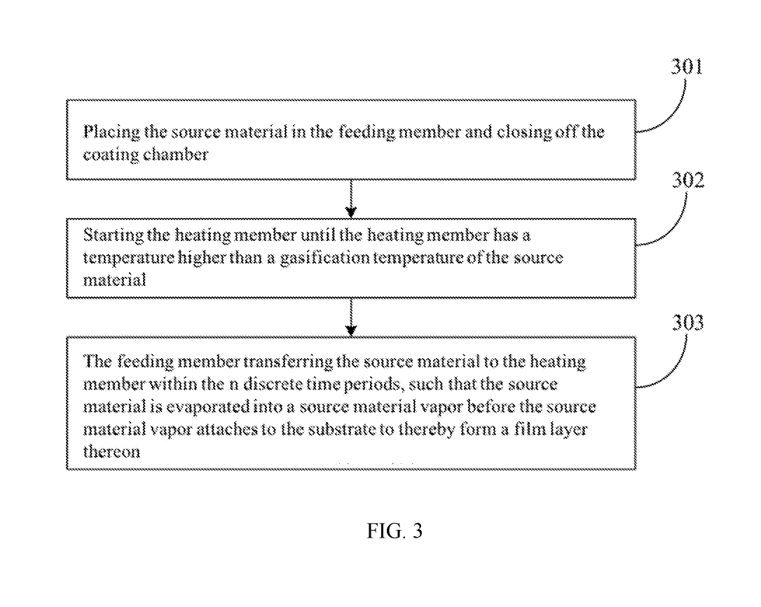

FIG. 3 illustrates a flowchart of an evaporation coating method according to some embodiments. The evaporation coating method utilizes an evaporation coating apparatus according to some embodiment of the present disclosure. The evaporation coating apparatus comprises an evaporator, a coating chamber, and an object holder. The object holder is configured to provide a platform for placing an object to be coated (such as a substrate) thereon. The evaporator comprises a feeding member and a heating member, wherein the feeding member is configured to store the source material and to transfer the source material to the heating member within n time periods.

The evaporation coating method can include the following steps.

Step 301: placing the source material in the feeding member and closing off the coating chamber;

Step 302: starting the heating member until the heating member has a temperature higher than a gasification temperature of the source material;

Step 303: the feeding member transferring the source material to the heating member within the n time periods, such that the source material is evaporated into a source material vapor before the source material vapor attaches to the substrate to thereby form a layer of the source material thereon.

In the evaporation coating method as described above, by means of the feeding member which can feed the source material to the heating member 12 within the n time periods, the issue of source material carbonization and the consequent negative effects on the evaporation coating process that is due to the piling up of a relatively large amount of source material in the heating member, and to an uneven heating by the heating member as well, can be effectively solved.

By means of the evaporation coating method as mentioned above, because there is a relatively small amount of source material for evaporation in the heating member, a relatively even heating can be realized, the source material is thus not subject to carbonization, ensuring that the evaporation coating process can normally proceed.

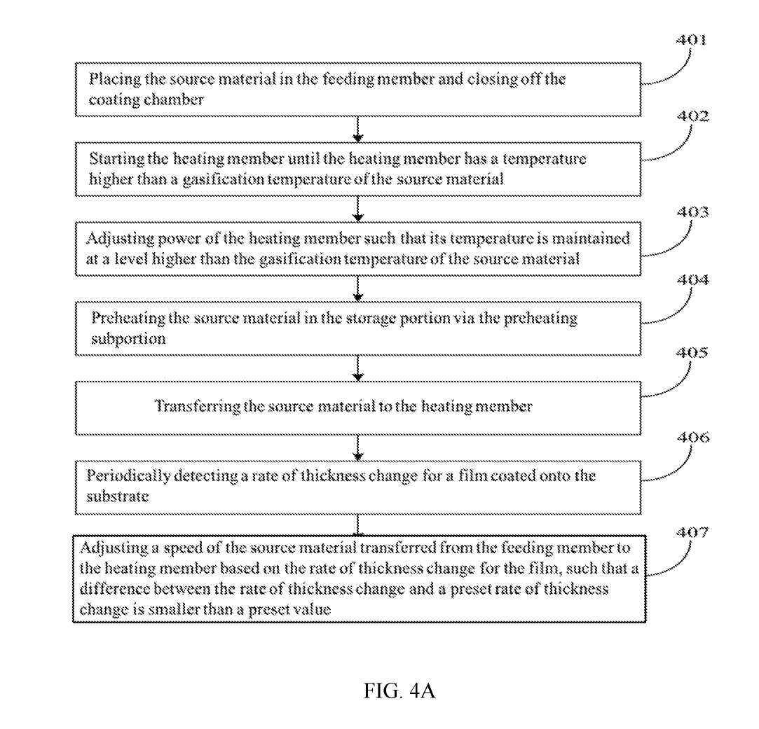

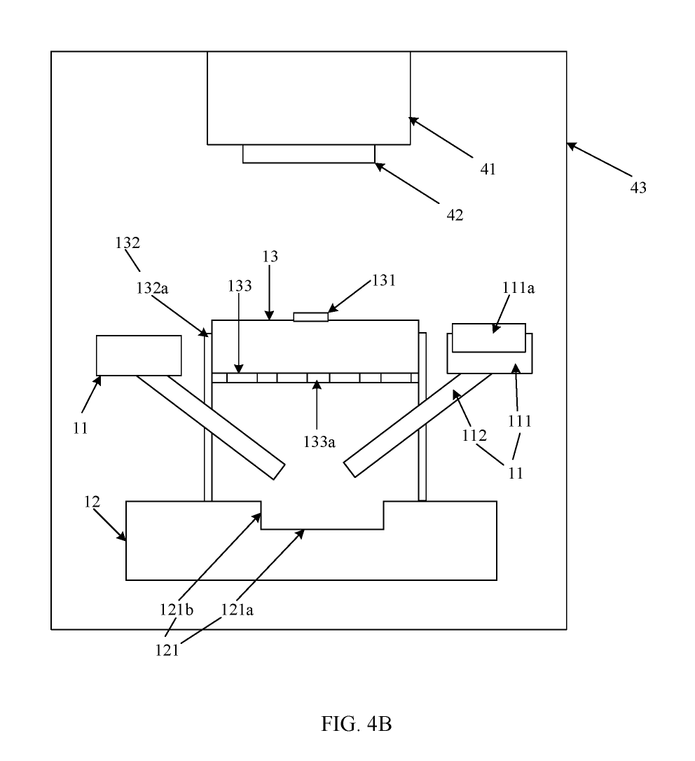

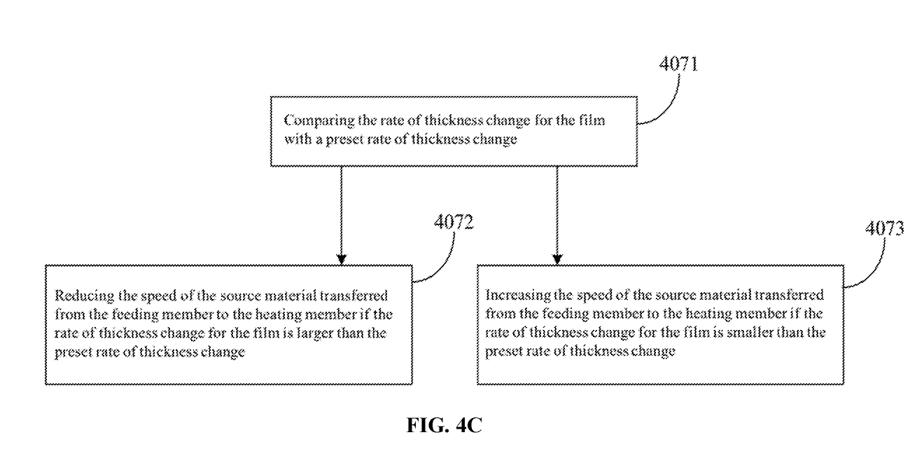

FIG. 4A illustrates a flowchart of an evaporation coating method according to some other embodiments of the present disclosure. The evaporation coating method utilizes an evaporation coating apparatus according to some embodiments of the present disclosure, which comprises an evaporator, a coating chamber, and an object holder. The object holder is configured to provide a platform for placing an object to be coated (such as a substrate) thereon. The evaporator comprises a feeding member and a heating member, wherein the feeding member is configured to store the source material and to transfer the source material to the heating member within n consecutive time periods.

The evaporation coating method can include the following steps.

Step 401: placing the source material in the feeding member and closing off the coating chamber.

When applying the evaporation coating method disclosed herein, the source material can be placed in the feeding member prior to the coating chamber is closed off. If there are more than one feeding member in the evaporation coating apparatus, the source material in each of the feeding members can have a same or a different parameter. The parameter can comprise at least one of a composition and a grain size of the source material.

In an example of the evaporation coating apparatus as shown in FIG. 4B, the reference numbers 41, 42 and 43 are respectively referred to as an object holder (41), an object (such as a substrate) to be coated (42), and a coating chamber (43). In Step 401, the source material can be placed in the feeding member 11 before the coating chamber 43 is closed off. Other reference numbers in FIG. 4B can be referenced to FIG. 2A.

Step 402: starting the heating member until a temperature of the heating member is higher than a gasification temperature of the source material.

After the coating chamber is closed off, the heating member can be started to increase the temperature of the heating member to a level higher than the gasification temperature of the source material.

Step 403: adjusting a power of the heating member such that the temperature of the heating member is maintained at a level higher than the gasification temperature of the source material;

After the heating member is started, its power can be adjusted to maintain the temperature of the heating member at a level higher than the gasification temperature of the source material, which can avoid a decrease of the temperature of the heating member caused by the subsequent addition of the source material. The decrease of the temperature of the heating member can negatively influence the evaporation of the source material.

Step 404: preheating the source material in the storage portion via the preheating subportion.

Before the source material is transferred to the heating member, the source material in the storage portion can be preheated via the preheating subportion 111a. The process of preheating can avoid a sharp increase of the temperature of the source material after the source material enters the heating member 12, which can damage the source material. The preheating temperature can be around 80° C. or around 50° C. The preheating subportion 111a can comprise a first heating wire surrounding the storage portion 111.

The feeding member 11 can comprise a storage portion 111, and a transferring portion 112, wherein the storage portion 111 is configured to store the source material, the transferring portion 112 is configured to transfer the source material to the heading member 12 within the n time periods, and the storage portion 111 is provided with the preheating subportion 111a.

Step 405: transferring the source material to the heating member.

After maintaining the temperature of the heating member at a level higher than the gasification temperature of the source material, the source material can be transferred to the heating member for the n time periods. Specifically, in one embodiment of the present disclosure, the source material can be separated into 10 portions, and each portion of the source material can be transferred to the heating member each time. As such, the evaporator can generate a stable flow of source material vapor. Each of the 10 portions of the source material can have a same mass or a different mass. There are no limitations herein.

Step 406: periodically detecting a rate of thickness change for a film coated onto the substrate;

After the source material is transferred to the heating member, the rate of thickness change for the film coated onto the substrate can be periodically detected. For example, the period can be set as 2 seconds, which means that the rate of thickness change for the film coated onto the substrate can be detected every two seconds.

As such, the evaporation coating apparatus can comprise a film thickness detector, which is configured to detect the rate of thickness change for the film coated onto the substrate. The film thickness detector can be a crystal oscillator.

Step 407: adjusting a speed of the source material transferred from the feeding member to the heating member based on the rate of thickness change for the film, such that a difference between the rate of thickness change and a preset rate of thickness change is smaller than a preset value;

After detecting the rate of thickness change for the film on the substrate, then based on the rate of thickness change for the film coated on the substrate, the speed of the source material transferred from the feeding member to the heating member can be adjusted such that the difference between the rate of thickness change for the film and the preset rate of thickness change for the film is smaller than the preset value.

Herein the speed of the source material transferred from the feeding member to the heating member is referred to as the amount of the source material that is transferred from the feeding member to the heating member per unit time, and it can substantially be the amount of the source material that is transferred from the feeding member to the heating member within each time period according to one of the embodiments as described above.

Step 407 ensures a stable rate of thickness change for the film on the substrate (i.e., a stable coating of the source material on the substrate), which in turn can improve the quality of coating.

Step 407 can comprise the following three sub-steps, as shown in FIG. 4C.

Sub-step 4071: comparing the rate of thickness change for the film with a preset rate of thickness change, and executing Sub-step 4072 if the rate of thickness change for the film is larger than the preset rate of thickness change, or otherwise executing Sub-step 4072.

Herein, the preset rate of thickness change for the film can be set by an operator in advance, for example, by programming a processor or a computer, which can be part of a controller configured to control the transfer speed.

Sub-step 4072: reducing the speed of the source material that is transferred from the feeding member to the heating member if the rate of thickness change for the film is larger than the preset rate of thickness change.

If the rate of thickness change is larger than the preset rate of thickness change, the speed of the source material that is transferred from the feeding member to the heating member can be controlled to be reduced to ensure a stable coating of the source material.

Herein, the speed of the source material that is transferred from the feeding member to the heating member is referred to as the amount of the source material that is transferred from the feeding member to the heating member per unit time, and it can substantially be the amount of the source material that is transferred from the feeding member to the heating member within each time period according to one of the embodiments as described above.

Because the temperature of the heating member is maintained at a level higher than the gasification temperature of the source material, the more the source material in the heating member, the faster the evaporation speed thereof. The larger the amount of the source material that is transferred to the heating member within each time period, the more the source material in the heating member (because the density of the source material is kept unchanged). As such, if the rate of thickness change is larger than the preset rate of thickness change, the amount of the source material transferred to the heating member within each time period can be reduced to thereby reduce the difference between the rate of thickness change and the preset rate of thickness change.

Sub-step 4073: increasing the speed of the source material that is transferred from the feeding member to the heating member if the rate of thickness change for the film is smaller than the preset rate of thickness change.

If the rate of thickness change is smaller than the preset rate of thickness change, the speed of the source material that is transferred from the feeding member to the heating member can be increased to ensure a stable coating of the source material.

Herein, the speed of the source material that is transferred from the feeding member to the heating member is referred to as the amount of the source material that is transferred from the feeding member to the heating member per unit time, and it can substantially be the amount of the source material that is transferred from the feeding member to the heating member within each time period according to one of the embodiments as described above.

In the evaporation coating method as described above, by means of the feeding member which can feed the source material to the heating member 12 within the n time periods, the issue of source material carbonization and the consequent negative effects on the evaporation coating process that is due to the piling up of a relatively large amount of source material in the heating member, and to an uneven heating by the heating member as well, can be effectively solved.

By employing the evaporation coating method as mentioned above, because there is a relatively small amount of source material for evaporation in the heating member, a relatively even heating can be realized, the source material is thus not subject to carbonization, ensuring that the evaporation coating process can normally proceed.

All references cited in the present disclosure are incorporated by reference in their entirety. Although specific embodiments have been described above in detail, the description is merely for purposes of illustration. It should be appreciated, therefore, that many aspects described above are not intended as required or essential elements unless explicitly stated otherwise.

Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. An evaporator, comprising:
at least one feeding member, each configured to transfer a source material in a transfer speed that is adjustable; and
a heating member, configured to heat the source material transferred by the feeding member for evaporation to thereby generate a source material vapor.

2. The evaporator of claim 1, wherein each feeding member is configured to transfer the source material to the heating member in portions, wherein:
each portion of the source material is transferred to the heating member in a time period; and
the time period for each portion is adjustable to thereby realize that the transfer speed is adjustable.

3. The evaporator of claim 2, wherein:
the source material is in a form of grains; and
each feeding member comprises a dispenser, configured to adjustably dispense the grains of the source material to allow the source material to be transferred to the heating member.

4. The evaporator of claim 3, wherein the dispenser comprises a vane wheel, configured to rotate to thereby dispense the grains of the source material for transferring to the heating member.

5. The evaporator of claim 4, wherein the vane wheel is coupled with a controller, configured to adjust a rotation speed of the vane wheel to thereby realize that the transfer speed of the source material is adjustable.

6. The evaporator of claim 1, wherein each feeding member comprises a storage portion and a transfer portion, wherein:
the storage portion is configured to store the source material before transferring to the transfer portion; and
the transfer portion is configured to transfer the source material from the storage portion to the heating member.

7. The evaporator of claim 6, wherein the storage portion comprises a preheating subportion, configured to preheat the source material in the storage portion.

8. The evaporator of claim 6, further comprising an evaporation chamber, wherein:
the heating member is disposed inside the evaporation chamber;
the storage portion of each feeding member is disposed outside the evaporation chamber; and
the evaporation chamber is provided with a vapor outlet, configured to vent the source material vapor out of the evaporation chamber for subsequent coating onto a substrate.

9. The evaporator of claim 8, the evaporation chamber is provided with a temperature controlling portion, configured to maintain a temperature of the evaporation chamber to thereby prevent the source material vapor from solidifying on an inner side of the evaporation chamber.

10. (canceled)

11. The evaporator of claim 8, wherein the evaporation chamber comprises a vapor flow stabilizing plate, wherein:
the vapor flow stabilizing plate is disposed inside the evaporation chamber to separate the heating member and the vapor outlet; and
the vapor flow stabilizing plate is provided with a plurality of openings, configured to allow the source material vapor generated from the heating member to move therethrough to subsequently vent out of the evaporation chamber through the vapor outlet.

12. The evaporator of claim 11, wherein:
each opening of the vapor flow stabilizing plate has a substantially same size and shape; and
a region closer to a center of the vapor flow stabilizing plate is configured to have a higher distribution density of openings.

13. The evaporator of claim 1, wherein each feeding member is configured to transfer a source material of a parameter, wherein the parameter comprises at least one of a composition, a shape, or a size.

14. The evaporator of claim 1, wherein the heating member comprises a heating groove, wherein:
the source material from the at least one feeding member is transferred into the heating groove; and
the heating groove comprises a bottom wall, and a side wall surrounding an edge of the bottom wall, wherein the bottom wall and the side wall are configured to be both able to heat.

15. An evaporation coating apparatus, comprising an evaporator according to claim 1.

16. The evaporation coating apparatus according to claim 15, further comprising a coating chamber, an object holder, and a controller configured to control the transfer speed; wherein:
the evaporator and the object holder are both disposed inside the coating chamber;
the object holder is configured to provide a platform for placing an object to be coated thereon; and
the coating chamber is configured to provide an environment for the source material vapor vented out from the evaporator to attach to the object to thereby form a film of the source material onto the object.

17. The evaporation coating apparatus according to claim 16, further comprising a film thickness detector, configured to detect a rate of thickness change for the film of the source material coated onto the substrate.

18. (canceled)

19. A method for evaporation coating of a source material on an object utilizing an evaporation coating apparatus, wherein the evaporation coating apparatus comprises an evaporator, a coating chamber, and an object holder, wherein the evaporator comprising at least one feeding member and a heating member, the method comprising:
placing the source material in the at least one feeding member and closing off the coating chamber;
starting the heating member until a temperature of the heating member is higher than a gasification temperature of the source material; and
the at least one feeding member transferring the source material to the heating member in a transfer speed that is adjustable to thereby obtain a source material vapor before the source material vapor attaches to the object to thereby form a film of the source material thereon.

20. The method according to claim 19, further comprising, between the starting the heating member until a temperature of the heating member is higher than a gasification temperature of the source material and the at least one feeding member transferring the source material to the heating member in a transfer speed that is adjustable:
adjusting a power of the heating member such that the temperature of the heating member is maintained at a level higher than the gasification temperature of the source material.

21. The method according to claim 19, further comprising, prior to the at least one feeding member transferring the source material to the heating member in a transfer speed that is adjustable:
preheating the source material.

22. The method according to claim 19, wherein:
the evaporation coating apparatus further comprises a film thickness detector configured to detect a rate of thickness change for the film of the source material coated onto the object; and
the at least one feeding member transferring the source material to the heating member in a transfer speed that is adjustable comprises:
the at least one feeding member transferring the source material to the heating member;
periodically detecting a rate of thickness change for the film of the source material coated onto the object; and
adjusting a transfer speed of the source material based on the rate of thickness change for the film of the source material, such that a difference between the rate of thickness change and a preset rate of thickness change is smaller than a preset value.

23. The method according to claim 22, wherein the adjusting a transfer speed of the source material based on the rate of thickness change for the film of the source material comprises:
comparing the rate of thickness change for the film of the source material with a preset rate of thickness change; and
reducing the transfer speed of the source material if the rate of thickness change for the film of the source material is larger than the preset rate of thickness change; or
increasing the transfer speed of the source material if the rate of thickness change for the film of the source material is smaller than the preset rate of thickness change.
